(19) United States
(12) Patent Application Publication
(10) Pub. No.: US 2026/0150631 A1
(43) Pub. Date: May 28, 2026

(54) Semiconductor Device

(71) Applicant: UNITED MICROELECTRONICS CORP., Hsin-Chu City (TW)

(72) Inventors: Jen-Hsien Chang, Taichung City (TW); Kai-Kuang Ho, Hsinchu City (TW); Meng-Ting Chiang, Taichung City (TW)

(73) Assignee: UNITED MICROELECTRONICS CORP., Hsin-Chu City (TW)

(21) Appl. No.: 19/011,642

(22) Filed: Jan. 7, 2025

(30) Foreign Application Priority Data
Nov. 27, 2024 (TW) 113145673

(51) Int. Cl. H01L 21/66; H01L 23/13

(52) U.S. Cl. CPC H10P 74/273; H10W 70/68

(57) ABSTRACT

A semiconductor device includes a multi-die package, a testkey region, and a scribe line. The multi-die package includes a plurality of dies each in a regular polygon shape, wherein each of the plurality of dies includes a number of sides, and the number is a multiplier of four and is greater than four. The testkey region is disposed between the plurality of dies and adjacent to one side of each of the plurality of dies. The testkey region is in an equilateral polygon shape. The scribe line surrounds a periphery of each of the plurality of dies and a periphery of the testkey region.

### BACKGROUND OF THE INVENTION

### 1. Field of the Invention

The present disclosure relates generally to a semiconductor device, and more particularly to a semiconductor device including a die in a regular polygonal shape.

### 2. Description of the Prior Art

In the modern society, the IC devices are becoming smaller, more delicate and more diversified. As well known in the art, an IC device is produced from dies that are fabricated by conventional semiconductor manufacturing processes. The process for manufacturing a die starts with a wafer: first, different regions are marked on the wafer; secondly, conventional semiconductor manufacture processes such as deposition, photolithography, etching or planarization are used to form circuit trace(s); then, each region of the wafer is diced to form a die, and the dies are then assembled to form a chip, so as to obtain a complete assembling unit. Finally, the chip is attached onto a board, such as a printed circuit board (PCB) by electrically connecting to the pins of the PCB. By doing so, functions on the chip can be executed accordingly to form numerous electronic devices. In order to achieve the miniaturization demands, a hybrid bonding (also known as “metal/dielectric hybrid bonding”) may be a direct bonding technology used by the advanced semiconductor industry to process the package of the die. However, the current design and the current die saw process of die will easily lead to low yield in the subsequent package process, and need to be further improved to meet the semiconductor industrial requirements.

### SUMMARY OF THE INVENTION

An object of the present disclosure is to provide a semiconductor device including a die in a regular polygonal shape, or including a multi-die package including a plurality of dies each in a regular polygonal shape, such that, each of the die will obtain the same distance from each side to a center thereof. Accordingly, the pressure is stressed on the semiconductor device of the present disclosure during a dicing process and/or a hybrid bonding process, in a more uniform manner, so as to gain the improved quality to the subsequent package process, and to avoid the low yield issue.

To achieve the aforementioned objects, the present disclosure provides a semiconductor device including a multi-die package, a testkey region, and a scribe line. The multi-die package includes a plurality of dies each in a regular polygonal shape, each of the plurality of dies includes a plurality of sides, and a number of the plurality of sides is a multiplier of four and is greater than four. The testkey region is disposed between the plurality of dies within the multi-die package, adjacent to at least one of the plurality sides of each of the plurality of dies. The testkey region is in an equilateral polygonal shape. The scribe line surrounds a periphery of each of the plurality of dies and a periphery of the testkey region.

To achieve the aforementioned objects, the present disclosure provides a semiconductor device including a die and a silicon scribe. The die includes a regular polygonal shape, wherein the die includes a plurality of sides, and a number of the plurality of sides is a multiplier of four and is greater than four. The silicon scribe line surrounds a periphery of the die.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 2 illustrate schematic diagrams of a semiconductor device according to a first embodiment of the present disclosure, in which:

FIG. 1 is a schematic top view of the semiconductor device; and

FIG. 2 is a schematic cross-sectional view taken along a cross-line A-A′ in FIG. 1.

FIG. 3 to FIG. 4 illustrate schematic diagrams of another semiconductor device according to a first embodiment of the present disclosure, in which:

FIG. 3 is a schematic top view of the another semiconductor device; and

FIG. 4 is a schematic cross-sectional view taken along a cross-line B-B′ in FIG. 3.

FIG. 5 to FIG. 6 illustrate schematic diagrams of a semiconductor device according to a second embodiment of the present disclosure, in which:

FIG. 5 is a schematic top view of the semiconductor device; and

FIG. 6 is another schematic top view of the semiconductor device.

FIG. 7 illustrates a schematic cross-sectional view of another semiconductor device according to a second embodiment of the present disclosure.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

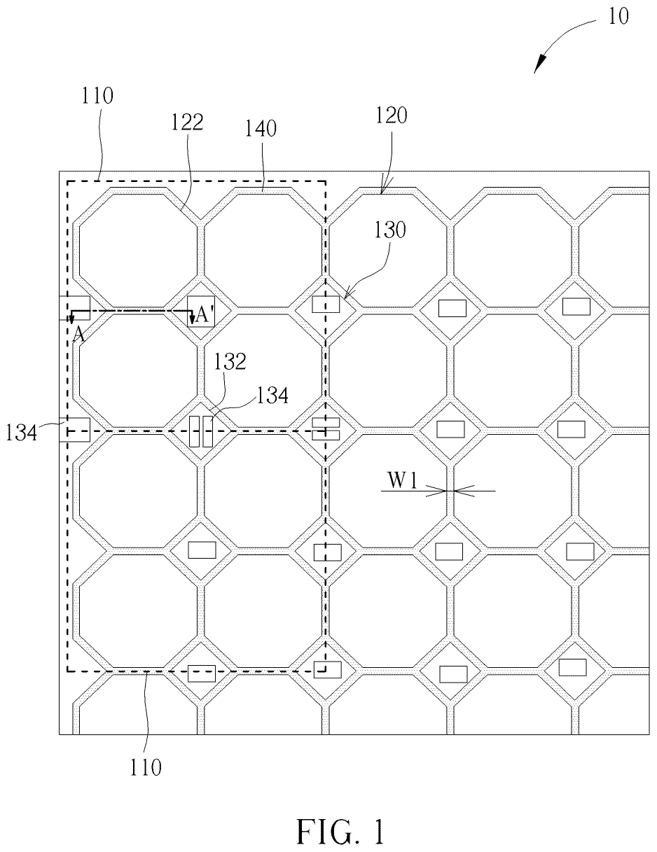

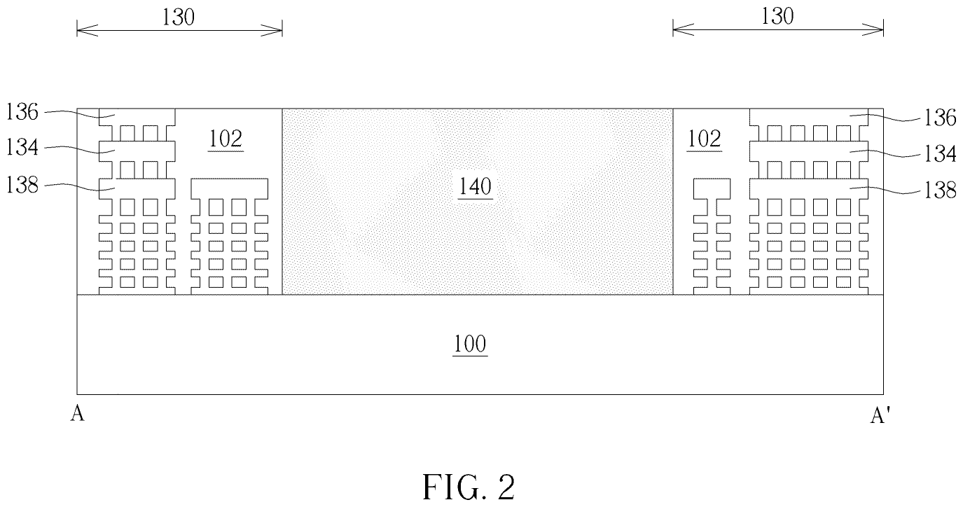

Please refer to FIG. 1 to FIG. 2, which are schematic diagrams of a semiconductor device 10 according to a first embodiment of the present disclosure, wherein FIG. 1 illustrates a schematic top view of the semiconductor device 10 and FIG. 2 illustrates a schematic cross-sectional view of the semiconductor device 10. Firstly, as shown in FIG. 1, the semiconductor device 10 includes a multi-die package 110, a testkey region 130 and a scribe line 140. The multi-die package 110 includes a plurality of dies 120 sequentially arranged with each other. In one embodiment, the semiconductor device 10 may include a plurality of the multi-die packages 110, with each of the multi-die packages 110 includes four dies 120 arranged with each other as shown in FIG. 1, but not limited thereto. In another embodiment, each multi-die package may optionally include the dies in another number or in another arrangement due to practical product requirement.

Each of the dies 120 for example includes a regular polygonal shape that has a plurality of sides 122 each in the same length, and a number of the plurality of sides 122 is a multiplier of four and is greater than four. Then, each of the dies 120 will present in a regular octagonal shape having eight sides 122 in the same length (as shown in FIG. 1), or in a regular dodecagon shape having twelve sides in the length, but not limited thereto. The testkey region 130 is disposed between the dies 120 within the multi-die package 110, and which is namely a region being together defined by one side 122 of each of the dies 120 within the multi-die package 110, being adjacent to each die 120 within the multi-die package 110. The testkey region 130 for example includes an equilateral polygonal shape which is different from the shape (the regular polygonal shape) of each die 120. Preferably, the testkey region 130 also includes a regular polygonal shape that has a plurality of edges 132 in the same length, and a number of the plurality of edges 132 is relative less than a number of the plurality of sides 122. For example, in the embodiment that the multi-die package 110 including four dies 120 and each die 120 is in a regular octagon shape (having eight sides in an equal length), and the testkey region 130 is together defined by one side 122 of each of the four regular octagon-shaped dies 120, thereby presenting in a regular quadrilateral shape having four edges 132 in the same length, as shown in FIG. 1, but not limited thereto. In other words, the number of dies 120 within the multi-die package 110 is defined by the minimum number of the dies 120 which is required to define a single testkey region 130.

The scribe line 140 is disposed around a periphery of each of the plurality of dies 120 and a periphery of the testkey region 130, and preferably only includes a silicon material. That is, there is no metal structure like a plug, a wire, a pad or an alignment mark disposed on the scribe line 140, as shown in FIG. 2, so as to prevent from uneven surfaces generated on the scribe line 140 after undergoing the subsequent die saw process. In one embodiment, the scribe line 140 for example includes a width W1, preferable being about 10 micrometers (μm) to 30 micrometers, but not limited thereto. It is noted that, since each die 120 disposed within the semiconductor device 10 of the present embodiment is in the regular polygonal shape, the distance from each side 122 to a center (not shown in the drawings) of the die 120 will be the same with each other, thereby preventing from the uneven stress occurred on the sides 122 so as to improve the bonding quality of the semiconductor device 10 in the subsequent process. In addition, since there is no metal structure disposed on the scribe line 140, the semiconductor device 10 will easily obtain an overall uniform surface after undergoing a die saw process performed subsequently. Then, the pressure may be stressed on each die 120 in the subsequent hybrid bonding process in a more uniform manner, during a chip-to-chip bonding or in a chip-to-wafer bonding, so that, each die 120 is allowable to gain a preferably quality in the subsequent packaging process, and to sufficient improve the low-yield issue.

Further in view of FIG. 1 and FIG. 2, the semiconductor device 10 further includes a substrate 100, and at least one testkey structure 134 and a bonding pad 136 disposed on the substrate 100. The substrate 100 for example includes a silicon substrate, an epitaxial silicon substrate, a silicon-containing substrate, or a silicon-on-insulator (SOI) substrate, and the aforementioned dies 120, the testkey region 130 and the scribe line 140 are respectively disposed on the substrate 100. Precisely speaking, the testkey structure 134 is disposed within the testkey region 130, and which includes a complete layout or at least a partial structure of any required element to be tested within the dies 120, with the at least one testkey structure 134 being corresponding to any active element or passive element like a transistor, a capacitor, a resistor, or even an analog circuit disposed on each die 120. Then, the structural health of these elements within each die 120 is allowable to be synchronously simulated by detecting the testkey structure 134. In one embodiment, each die 120 for example includes at least one interconnection structure (not shown in FIG. 2) disposed on the substrate 100, with the at least one interconnection structure for example including a plurality wires and a plurality of plug structures stacked in sequence. The at least one interconnection structure may include a low-resistant metal material like copper (Cu), aluminum (Al), tungsten (W), or titanium (Ti), and preferably including copper, but not limited thereto. On the other hand, the testkey region 130 correspondingly includes the at least one testkey structure 134 also disposed on the substrate 100, as shown in FIG. 2, for detecting the structural health of the at least one interconnection structure in the subsequent simulating process. Also, in the embodiment that the semiconductor device 10 including a plurality of the multi-die packages 110, the testkey structures 134 correspondingly disposed in a plurality of the testkey regions 130 may respectively include an active element, a passive element, an alignment mark, a wafer acceptance test pad, or an analog circuit being different from each other.

The at least one testkey structure 134 is disposed in a dielectric layer 102 on the substrate 100, within the testkey region 130, and which can be coupled to an active element, a passive element, or a circuit (not shown in the drawings) disposed either on the substrate 100 or in the substrate 100 through an interconnection structure 138 disposed underneath. The testkey structure 134 also includes a low-resistant metal material such as copper, aluminum, tungsten, or titanium, and preferably including copper, but not limited thereto. The bonding pad 136 is disposed on the at least one testkey structure 134 to electrically connect thereto. It is noted that, a surface of the bonding pad 136 is exposed from the dielectric layer 102, so that, the semiconductor device 10 can be further electrically connected to another die or another semiconductor device through the bonding pad 136, based on practical product requirements. In one embodiment, the formation of the scribe line 140 is for example accomplished by firstly forming a trench (not shown in the drawings) between each die 120 and the testkey region 130 by partially etching the dielectric layer 102, next filling in the trench with a silicon material like single-crystal silicon, polysilicon, or amorphous silicon by performing a deposition process or an epitaxial growing process, and finally obtaining the scribe line 140 only including the silicon material by performing a planarization process to remove the redundant silicon material.

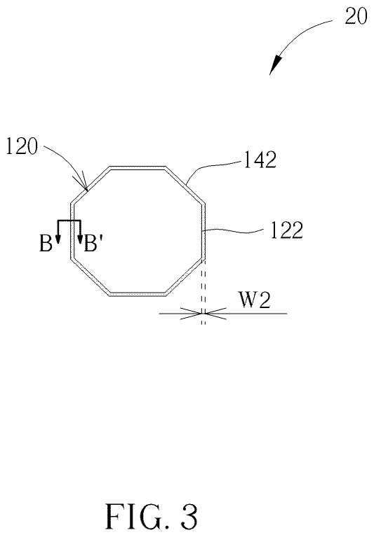

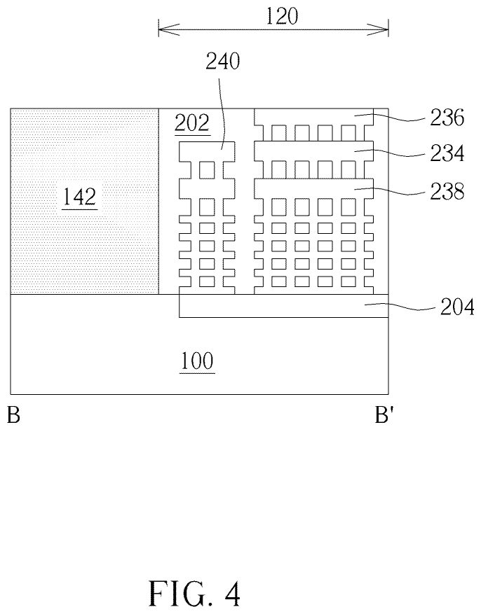

Through these arrangements, the semiconductor device 10 can be further diced into a plurality of dies 120 as shown in FIG. 3 and FIG. 4 through processing the scribe line 140 in the subsequent die saw process such as a laser dicing process or a plasma dicing process, but not limited thereto. In another embodiment, the semiconductor device 10 may also be diced into the dies 120 through selectively etching the silicon material of the scribe line 140, for example by performing an etching process. According to the semiconductor device 10 of the present embodiment, since the scribe line 140 only includes the silicon material without any metal structures disposed thereon, the width of the scribe line 140 will be dramatically shrunk, and the possible issues like metal residues, uneven surface, or pealing film will be sufficiently improved. For example, the width W1 of the scribe line 140 disposed around each of the dies 120 may be about 10 micrometers to 30 micrometers, but not limited thereto. On the other hand, since each die 120 disposed within the semiconductor device 10 of the present embodiment is in the regular polygonal shape, the distance from each side 122 to the center of the die 120 will be the same with each other. Then, the pressure will be stressed on each side 122 of the die 120 in the subsequent hybrid bonding process in a more uniform manner, as being bonded to another die (not shown in the drawing) or another wafer (not shown in the drawing), thereby preventing from the uneven stress easily occurred on each side 122. Thus, the semiconductor device 10 of the present embodiment is allowable to gain a preferably quality in the subsequent packaging process, and to sufficient improve the low-yield issue.

Please refer to FIG. 3 and FIG. 4, which are schematic diagrams of another semiconductor device 20 according to the first embodiment of the present disclosure, wherein FIG. 3 illustrates a schematic top view of the semiconductor device 20 and FIG. 4 illustrates a schematic cross-sectional view of the semiconductor device 20. Firstly, as shown in FIG. 3, the semiconductor device 20 includes a single die 120 and a scribe line 240. The structure of the die 120 within the semiconductor device 20 is substantially the same as that of each die 120 within the semiconductor device 10, and all the similarity will not be redundantly described hereinafter. The die 120 includes the regular polygonal shape that has the plurality of sides 122 in the same length, with the number of the plurality of sides 122 being a multiplier of four and greater than four, preferably for eight, but not limited thereto. Then, the scribe line 142 is disposed around the periphery of the die 120.

It is noted that, since there is no metal structure like a plug, a wire, a pad or an alignment mark disposed on the scribe line 142, a width W2 of the scribe line 142 surrounding outside the periphery of the die 120 will be dramatically shrunk thereby, for example preferably being about 2.5 micrometers to 12.5 micrometers, but not limited thereto. As shown in FIG. 4, the die 120 precisely includes at least one interconnection structure 234 and a conductive pad 236 disposed on the substrate 100. The at least one interconnection structure 234 is disposed within a dielectric layer 202 disposed on the substrate 100, and which includes the same material and the same structure as that of the at least one testkey structure 134. The at least one interconnection structure 234 may be further electrically connected to a doped region 204 in the substrate 100 through another interconnection structure 238 disposed underneath. The conductive pad 236 is disposed on the at least one interconnection structure 234, with a surface thereof being exposed from the dielectric layer 202. Furthermore, a protection structure 240 such as a guard ring may be additionally disposed at the periphery of the die 120.

Through these arrangements, the subsequent packaging process may be further performed on the die 120 of the semiconductor device 20, for example attaching the semiconductor device 20 to a circuit board (not shown in the drawings) or other secondary packaging substrates via the bonding pad 236 disposed on the die 120, to form the required integrated circuits. Alternatively, the die 120 may also be used directly as a chip scale package (CSP) of the wafer-level package, which is beneficial on thin and short packaging application. In this way, since the die 120 of the present embodiment is in the regular polygonal shape, the distance from each side 122 to the center of the die 120 will be the same with each other, thereby preventing from the uneven stress occurred on the sides 122 in the subsequent hybrid bonding process, during a chip-to-chip bonding or in a chip-to-wafer bonding. Accordingly, the die 120 is allowable to gain a preferably quality in the subsequent packaging process, and to sufficient improve the low-yield issue.

People well-skilled in the art should fully understand that the semiconductor device is not limited to be what is shown in the aforementioned embodiments, and which may further include other examples based on practical product requirements. The following description will detail other different embodiments or variant embodiments of the semiconductor device in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

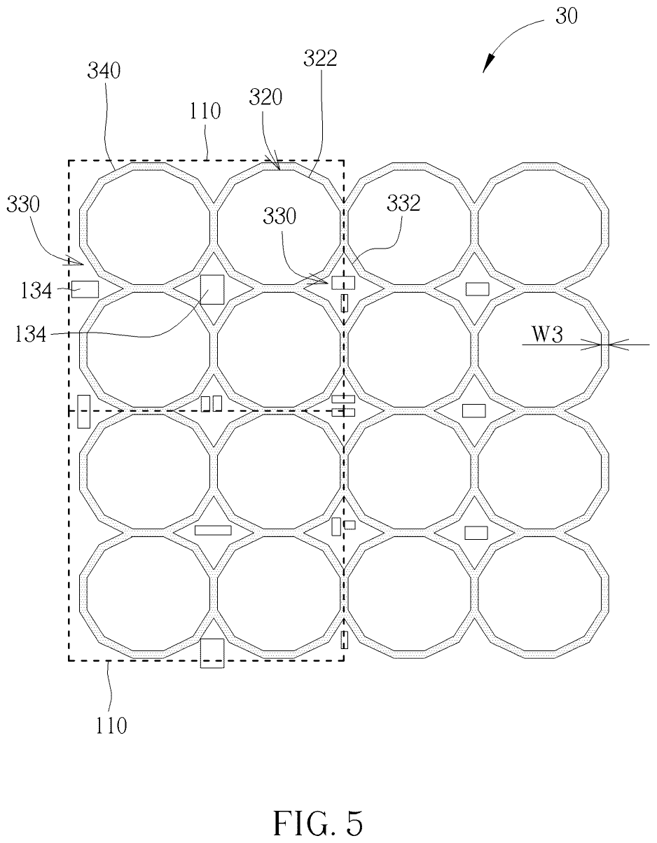

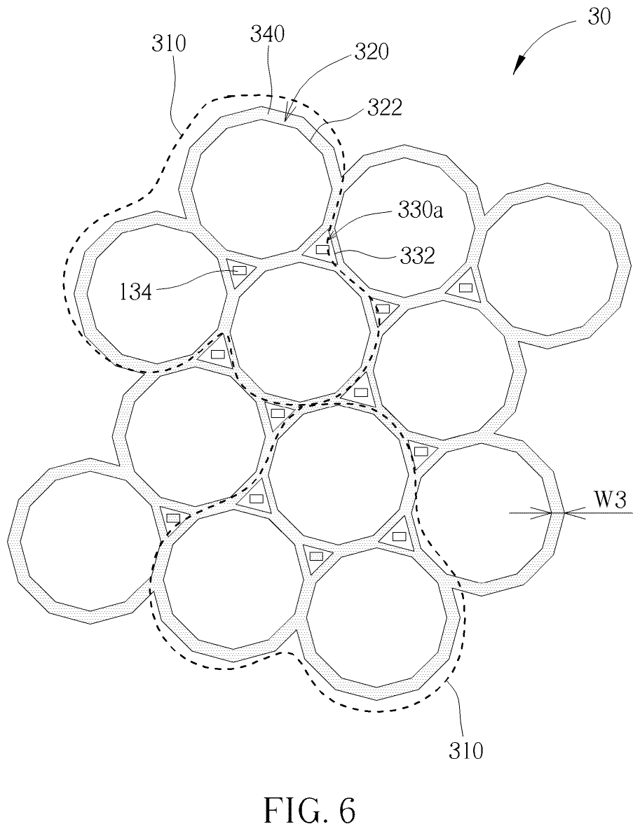

Please refer to FIG. 5 and FIG. 6, which are schematic diagrams of a semiconductor device 30 according to a second embodiment of the present disclosure, wherein FIG. 5 illustrates a schematic top view of the semiconductor device 30 and FIG. 6 illustrates another schematic top view of the semiconductor device 30. The structure of the semiconductor device 30 in the present embodiment is substantially the same as that of the semiconductor device 10 in the aforementioned embodiment, and all the similarities will not be redundantly described hereinafter. The difference between the present embodiment and the aforementioned embodiment is mainly in the shape of dies 320 and/or the number and the arrangement of the dies 320 within the multi-die package 110, 310.

Precisely speaking, as shown in FIG. 5, the multi-die package 110 for example includes four dies 320 arranged sequentially, and each of the dies 320 is in a regular dodecagonal shape including twelve sides 322 in the same length. The testkey region 330 is disposed between the dies 320 within the multi-die package 110, and includes a region being together defined by at least two sides 322 of each of the dies 320 within the multi-die package 310, thereby present in an equilateral polygonal shape which is different from the shape of each die 320, for example being in an equilateral octagonal shape as shown in FIG. 5, but not limited thereto. That is, the testkey region 330 includes eight edges 322 each in the same length, and the distance from each edge 322 to a center (not shown in the drawings) of the testkey region 330 is not the same with each other. However, in another embodiment, the multi-die package 310 may optionally include three dies 320 arranged sequentially, and the testkey region 330a will be a region being together defined by one sides 322 of each of the dies 320 within the multi-die package 310, thereby present in an equilateral triangular shape (including three edges 322 in the same length) which is different from the shape of each die 320 as shown in FIG. 6, but not limited thereto. That is, in the embodiment that the multi-die package 310 including three dies 320, the number of dies 320 within the multi-die package 310 is also defined by the minimum number of the dies 320 which is required to define a single testkey region 330a.

On the other hand, the semiconductor device 30 includes a scribe line 340 disposed around a periphery of each of the plurality of dies 320 and a periphery of the testkey region 330/330a, and preferably only includes a silicon material. In other words, there is no metal structure like a plug, a wire, a pad or an alignment mark disposed on the scribe line 340, so that, each die 320 will easily obtain the overall even surface after undergoing the subsequent die saw process. Accordingly, since each die 320 disposed within the semiconductor device 30 of the present embodiment is in the regular polygonal shape (namely, the regular dodecagonal shape), the bonding quality in the subsequent hybrid bonding process will be dramatically improved, without leading to the uneven pressure possibly stressed on the sides 322 of the dies 320. Also, since there is no metal structure disposed on the scribe line 340, a width W3 of the scribe line 342 will be dramatically shrunk thereby, for example preferably being about 10 micrometers to 30 micrometers, so as to gain a preferably quality in the subsequent packaging process, and to sufficient improve the low-yield issue.

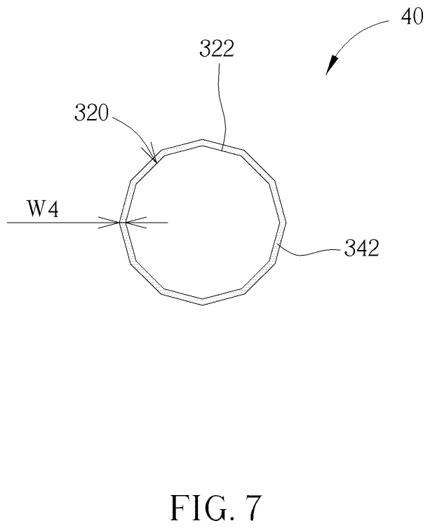

Through these arrangements, the semiconductor device 30 also can be further diced into a plurality of the dies 320 as shown in FIG. 7 through processing the subsequent die saw process such as a laser dicing process or a plasma dicing process on the scribe line 340. As shown in FIG. 7, a schematic top view of another semiconductor device 40 according to the second embodiment of the present disclosure is illustrated. The semiconductor device 40 includes a single die 320 and a scribe line 342. The die 320 is preferably in a regular dodecagonal shape, and includes twelve sides 322 with the same length. The scribe line 342 is disposed around the periphery of the die 320. It is noted that there is no metal structures like a plug or a wire disposed on the scribe line 342, so that, a width W4 of the scribe line 342 surrounding outside the periphery of the die 320 will be dramatically shrunk thereby, for example preferably being about 2.5 micrometers to 12.5 micrometers, but not limited thereto.

The structure of the die 320 within the semiconductor device 40 is substantially the same as that of each die 320 within the semiconductor device 30, and all the similarity will not be redundantly described hereinafter. Then, the subsequent packaging process may be further performed on the die 320 of the semiconductor device 40, for example attaching the semiconductor device 40 to a circuit board (not shown in the drawings) or other secondary packaging substrates via a bonding pad (not shown in the drawings) disposed on the die 320, to form the required integrated circuits.

According to the semiconductor device in the present disclose, since a scribe line disposed within the semiconductor device only includes the silicon material without including any metal structures disposed thereon, the possible issues like metal residues, uneven surface, or pealing films will be sufficiently improved, the width of the scribe line will be dramatically shrunk, and the subsequent die saw process will be simplified thereby. Also, since a die or a plurality of dies of a multi-die package disposed within the semiconductor device is in the regular polygonal shape, the distance from each side to the center of the die will be the same with each other. Then, the pressure stressed on each die in the subsequent die saw process and/or the subsequent hybrid bonding process will be carried out in a more uniform manner, so that, the die is allowable to gain a preferably quality in the subsequent packaging process, and to sufficient improve the low-yield issue.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a multi-die package, comprising a plurality of dies each in a regular polygon shape, wherein each of the plurality of dies comprises a plurality of sides, and a number of the plurality of sides is a multiplier of four and is greater than four;
a testkey region, disposed between the plurality of dies within the multi-die package, and adjacent to at least one of the plurality sides of each of the plurality of dies, the testkey region being in an equilateral polygonal shape; and
a scribe line, surrounding a periphery of each of the plurality of dies and a periphery of the testkey region.

2. The semiconductor device according to claim 1, wherein the testkey region comprises a plurality of edges, and a number of the plurality of edges is less than the number of the plurality of sides of each of the plurality of dies.

3. The semiconductor device according to claim 2, wherein the number of the plurality of sides of each of the plurality of dies is eight.

4. The semiconductor device according to claim 2, wherein the number of the plurality of sides of each of the plurality of dies is twelve.

5. The semiconductor device according to claim 3, wherein the number of the plurality of edges of the testkey region is four.

6. The semiconductor device according to claim 4, wherein the number of the plurality of edges of the testkey region is eight.

7. The semiconductor device according to claim 6, wherein a number of the plurality of dies within the multi-die package is four.

8. The semiconductor device according to claim 4, wherein the number of the plurality of edges of the testkey region is three.

9. The semiconductor device according to claim 8, wherein a number of the plurality of dies within the multi-die package is three.

10. The semiconductor device according to claim 1, wherein the scribe line only comprises a silicon material.

11. The semiconductor device according to claim 1, wherein a width of the scribe line is between 10 μm and 30 μm.

12. The semiconductor device according to claim 1, further
comprising:
at least one testkey structure, disposed in the testkey region.

13. The semiconductor device according to claim 12, further
comprising:
a substrate, the testkey region and the scribe line are respectively disposed on the substrate;
at least one interconnection structure, disposed on the substrate and within each of the plurality of die, the at least one interconnection structure comprises a same structure as that of the at least one testkey structure; and
a conductive pad, disposed on the at least one testkey structure.

14. A semiconductor device, comprising:
a die, comprising a regular polygon shape, wherein the die comprises a plurality of sides, and a number of the plurality of sides is a multiplier of four and is greater than four; and
a scribe line, surrounding a periphery of the die.

15. The semiconductor device according to claim 14, wherein the number of the plurality of sides is eight.

16. The semiconductor device according to claim 14, wherein the number of the plurality of sides is twelve.

17. The semiconductor device according to claim 14, wherein the scribe line only comprises a silicon material.

18. The semiconductor device according to claim 17, wherein a width of the scribe line is between 2.5 μm and 12.5 μm.

19. The semiconductor device according to claim 18, the die further comprising:
a substrate; and
at least one interconnection structure, disposed on the substrate.
